(19) United States
(12) Patent Application Publication
(10) Pub. No.: US 2022/0293416 A1
(43) Pub. Date: Sep. 15, 2022

(54) SYSTEMS AND METHODS FOR IMPROVED CARBON ADHESION

(71) Applicant: Applied Materials, Inc., Santa Clara, CA (US)

(72) Inventors: Sudha S. Rathi, San Jose, CA (US); Ganesh Balasubramanian, Fremont, CA (US); Tae Won Kim, San Jose, CA (US)

(73) Assignee: Applied Materials, Inc., Santa Clara, CA (US)

(21) Appl. No.: 17/200,008

(22) Filed: Mar. 12, 2021

(51) Int. Cl. H01L 21/02; H01L 21/033; H01J 37/32; C23C 16/50; C23C 16/26; C23C 16/44

(52) U.S. Cl. CPC H01L 21/02274; H01L 21/0332; H01L 21/02115; H01J 37/32862; H01J 37/32532; C23C 16/50; C23C 16/26; C23C 16/4405; H01J 2237/332

(57) ABSTRACT

Exemplary methods of semiconductor processing may include forming a plasma of a carbon-containing precursor and an inert precursor within a processing region of a semiconductor processing chamber. The methods may include, subsequent a first period of time, increasing a flow rate of the carbon-containing precursor and a flow rate of the inert precursor. The methods may include increasing a plasma power at which the plasma is formed. The methods may include performing a deposition process on a semiconductor substrate disposed within the processing region of the semiconductor processing chamber.

### TECHNICAL FIELD

The present technology relates to methods and components for semiconductor processing. More specifically, the present technology relates to deposition processes and chamber components.

### BACKGROUND

Integrated circuits are made possible by processes which produce intricately patterned material layers on substrate surfaces. Producing patterned material on a substrate requires controlled methods for forming and removing material. Deposition processes may form material that attaches to many components of the system. This material may fall back on to wafers as defects subsequent the deposition processes, which may cause device failure depending on the extent of defect incorporation.

Thus, there is a need for improved systems and methods that can be used to produce high quality devices and structures. These and other needs are addressed by the present technology.

### SUMMARY

Exemplary methods of semiconductor processing may include forming a plasma of a carbon-containing precursor and an inert precursor within a processing region of a semiconductor processing chamber. The methods may include, subsequent a first period of time, increasing a flow rate of the carbon-containing precursor and a flow rate of the inert precursor. The methods may include increasing a plasma power at which the plasma is formed. The methods may include performing a deposition process on a semiconductor substrate disposed within the processing region of the semiconductor processing chamber.

In some embodiments, the deposition process may include forming a carbon-containing hardmask film. The carbon-containing precursor and the inert precursor may be flowed through a faceplate into the processing region of the semiconductor processing chamber. The faceplate may be coated with an oxide of aluminum, silicon, yttrium, hafnium, or zirconium. The methods may include, subsequent the first period of time, reducing a pressure within the semiconductor processing chamber. The methods may include performing a chamber clean with an oxygen-containing precursor. The plasma power may be increased from a first plasma power of less than or about 1000 W to a second plasma power of greater than or about 2000 W. The methods may include, subsequent the first period of time, adjusting a spacing of a substrate support on which the semiconductor substrate is disposed. The flow rate of the carbon-containing precursor may be increased less than the flow rate of the inert precursor subsequent the first period of time. The first period of time may be less than or about 1 minute.

Some embodiments of the present technology may encompass semiconductor processing methods. The methods may include forming a plasma of a carbon-containing precursor and an inert precursor within a processing region of a semiconductor processing chamber. The methods may include, subsequent a first period of time, lowering a pressure within the processing region while continuing to form the plasma of the carbon-containing precursor and an inert precursor within a processing region of a semiconductor processing chamber. The methods may include performing a deposition process on a semiconductor substrate disposed within the processing region of the semiconductor processing chamber.

In some embodiments, the methods may include, subsequent the first period of time, increasing a plasma power from a first plasma power below or about 1000 W to a second plasma power greater than or about 2000 W. The methods may include, subsequent the first period of time, increasing a flow rate of the carbon-containing precursor and a flow rate of the inert precursor. the flow rate of the carbon-containing precursor may be increased less than the flow rate of the inert precursor subsequent the first period of time. The carbon-containing precursor and the inert precursor may be flowed through a faceplate into the processing region of the semiconductor processing chamber. The faceplate may be coated with an oxide of aluminum, silicon, yttrium, hafnium, or zirconium. The first period of time may be less than or about 1 minute. The methods may include, subsequent the first period of time, adjusting a spacing of a substrate support on which the semiconductor substrate is disposed.

Some embodiments of the present technology may encompass semiconductor processing methods. The methods may include forming a plasma of a carbon-containing precursor and an inert precursor within a processing region of a semiconductor processing chamber. The methods may include, subsequent a first period of time, increasing a flow rate of the carbon-containing precursor and a flow rate of the inert precursor. The flow rate of the carbon-containing precursor may be increased less than the flow rate of the inert precursor subsequent the first period of time. The methods may include performing a deposition process on a semiconductor substrate disposed within the processing region of the semiconductor processing chamber.

In some embodiments, the methods may include, subsequent the first period of time, reducing a pressure within the semiconductor processing chamber. The methods may include, subsequent the first period of time, increasing a plasma power within the processing region. The plasma power may be increased from a first plasma power of less than or about 1000 W to a second plasma power of greater than or about 2000 W. The carbon-containing precursor and the inert precursor may be flowed through a faceplate into the processing region of the semiconductor processing chamber. The faceplate may be coated with a metal oxide. The methods may include, subsequent the first period of time, adjusting a spacing of a substrate support on which the semiconductor substrate is disposed.

Such technology may provide numerous benefits over conventional systems and techniques. For example, embodiments of the present technology may provide chamber treatments that reduce fall-on particles during a number of deposition processes. Additionally, the present technology may reduce processing drift over time due to oxide development on chamber components. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. However, the formed materials may not be deposited solely on the substrate. For example, materials formed with an in situ plasma may deposit on many surfaces within the processing region, such as chamber walls, substrate supports, showerheads, or other components. Often, additional cleaning operations may be performed within the chamber, which may also be plasma-based to remove deposited materials from the surfaces. However, the cleaning may occur subsequent substrate removal from the chamber, and fall-on particle deposition may often occur while the substrate remains within the processing region of the chamber.

For example, in one exemplary deposition process for a hard mask material, a carbon-based material may be deposited to produce a carbon or carbon-containing film on the substrate. The carbon film may deposit on a number of chamber components as well, although adhesion of carbon on some materials may be limited. The deposited material may flake off from the chamber components, and fall onto the substrate. Additionally, a number of particles may be trapped within the plasma during the formation. Once the plasma is extinguished, the particles may fall to the substrate.

The cleaning process regularly used for carbon-containing films may include formation of an oxygen-containing plasma, which may strip residual carbon materials from chamber components and remove it from the chamber as carbon dioxide or other volatile materials.

However, this radical oxygen may also impact chamber components. Many chamber components are formed of aluminum, which may oxidize when exposed to oxygen, and the oxygen exposure occurring during cleaning operations may cause a number of issues. For example, a faceplate may be used as a powered electrode in many processing chambers, or as a ground electrode. When operating as a powered electrode, the oxidation of the aluminum may cause emissivity changes for the electrode, which may impact plasma generation and uniformity. The oxidation may not occur uniformly across the faceplate, and over time process drift may result.

As oxide buildup occurs on some regions of the faceplate more than others, such as within apertures through the faceplate, flow properties may also become less uniform. These challenges may cause process drift, which can impact deposition precision and lead to increased downtime, component replacement, or wafer scrap. To address this impact due to oxidation of the powered electrode, an oxide coating may be formed on the faceplate prior to installation in the processing chamber. The oxide coating can be formed more uniformly, and may be a higher quality oxide than may form during the radical oxygen exposure. The oxide may be formed on all exposed surfaces of the electrode, including within apertures, or may be selectively formed or applied on plasma-facing or substrate facing regions of the faceplate. While this may address process drift due to oxide formation process-to-process, the oxide coated faceplate may produce new challenges.

As noted above, formation of carbon films may cause deposition on many exposed surfaces within a processing region of the chamber where the plasma production may occur. While the oxide-coated faceplate may improve process drift during the cleaning operations, the coating may also limit adhesion of carbon films on the faceplate. The oxygen superficially incorporated along the faceplate may have limited bonding with carbon, and this effect may limit adhesion between the carbon films being formed and the oxide-coated faceplate. This limited adhesion may cause particles and flakes to fall from the faceplate onto the substrate during film growth causing defects in the film. Because the film produced may be utilized as a hardmask, these defects may impact subsequent processing to the detriment of operational precision. Additionally, these residual carbon flakes may produce conductive paths to grounded surfaces, which may cause stray arcing that can damage chamber components and further impact processing.

Because of the challenges associated with particle formation in this way, conventional technologies have been limited to aluminum components that lead to further process drift, or coated components that may impact device quality. The present technology overcomes these challenges by performing an initiation process during deposition that may improve carbon adhesion on oxide-coated electrodes. By increasing a carbide-like development at an interface of the faceplate, subsequent deposition may allow improved adhesion of carbon-containing films to the faceplate during deposition. Aspects of the processing chamber and processing conditions may also be adjusted in some embodiments of the present technology to further reduce fall on particles. Additionally, by utilizing oxide-coated electrodes, subsequent cleaning operations may have reduced or limited impact on the faceplate, improving throughput and uniformity across substrates being processed.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may include components and may be operated according to embodiments of the present technology before additional variations and adjustments to this system according to embodiments of the present technology are described.

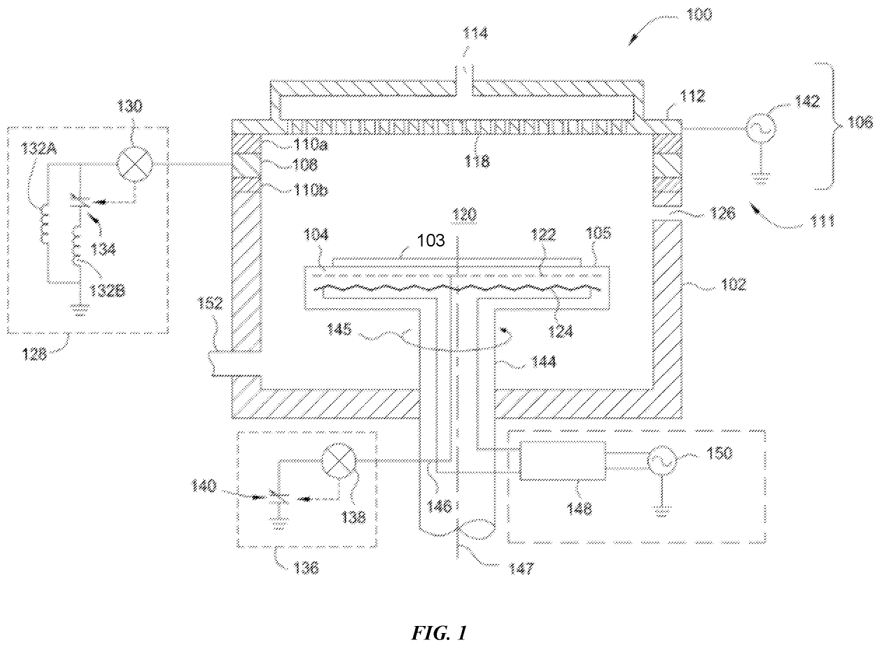

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

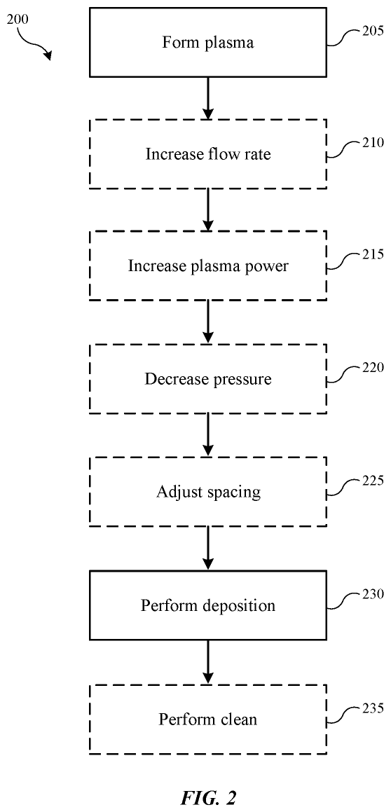

FIG. 2 shows exemplary operations in a processing method 200 according to some embodiments of the present technology. The method may be performed in a variety of processing chambers, including processing system 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 200 may include a processing method that may utilize an initiation period during a deposition operation to induce formation of improved bonding between materials to be deposited and chamber surfaces that may be treated, such as with an oxide coating. The method may include optional operations prior to the start of method 200, or the method may include additional operations. Method 200 may include operations performed in different orders than illustrated. For example, the method may be performed subsequent a previous chamber clean in some embodiments. As described previously, cleaning operations may utilize plasma enhanced oxygen or other etchant precursors. Oxygen effluents may interact with aluminum chamber components as discussed above, which may cause aluminum oxide to form and challenge uniform plasma processing, as well as issues with adhesion of carbon materials on oxidized components. In some embodiments, method 200 may be performed in a processing chamber including a faceplate, such as gas distributor 112 discussed above, which may have an oxide coating formed on the component, although it is to be understood that the method may also be performed with uncoated chamber components. The coating may be a metal oxide coating formed or developed on the faceplate, which may be aluminum or some other material used for components in plasma processing chambers. The metal oxide coating may include any number of metals that may facilitate reduction in erosion or corrosion during plasma processing. For example, the oxide used in the coating may be developed from aluminum, silicon, yttrium, zirconium, hafnium, or any other metal, transition metal, post-transition metal, metalloid, or combination of metals.

The oxide coated faceplate may be installed in a processing chamber, when used, and method 200 may be performed on a substrate positioned within the processing chamber, such as on substrate support 104. Although the remaining disclosure may discuss development of a carbon-containing film, it is to be understood that the present technology may encompass a deposition process, a removal process, or some other semiconductor process that may be performed on the substrate within the processing region of the chamber, or may involve cleaning or processing that may utilize an oxygen-containing plasma. In one exemplary deposition process encompassed by the present technology, a carbon-containing hardmask, such as a carbon film or a carbon-containing film, may be deposited on the substrate.

As discussed above, carbon-containing films may have insufficient adhesion with oxide surfaces and carbon-oxygen bonding may not readily form across the structure. Accordingly, the present technology may initiate a deposition operation with process conditions that increase carbon bonding with the metal of the metal oxide, such as aluminum, silicon, or any other metal as noted above. By forming several monolayers of a carbide-like film prior to performing increased deposition operations, an interfacial layer may be produced that increases a surface energy and reduces a contact angle to be closer to that of a carbon film. The resultant interfacial layer may facilitate subsequent film adhesion with materials that may have increased hydrogen content as material deposition is increased. In some embodiments of the present technology, the method may be performed with a transition between the initiation conditions and the deposition conditions where processing conditions may be adjusted in situ, such as while maintaining plasma generation and/or precursor delivery. Because the initiation process may be performed for a discrete amount of time, and because a relatively thin layer of interfacial material may be produced to facilitate adhesion improvements, an impact on the film as being deposited on the substrate may be limited.

Method 200 may include developing a plasma of deposition precursors at operation 205. The method may include flowing one or more carbon-containing materials into a processing region and one or more inert precursors into the processing region and forming a plasma within a processing region of the processing chamber. The chamber conditions and conditions for plasma development may be formed to increase an interface layer on a faceplate as well as any other exposed chamber components. After a first period of time, one or more conditions may be adjusted to transition to a deposition operation for developing a film on the semiconductor substrate. Because the interfacial layer may be less than or about a nanometer as well a few monolayers or less, the first period of time may be less than or about one minute, and may be less than or about 55 seconds, less than or about 50 seconds, less than or about 45 seconds, less than or about 40 seconds, less than or about 35 seconds, less than or about 30 seconds, less than or about 25 seconds, less than or about 20 seconds, less than or about 15 seconds, less than or about 10 seconds, less than or about 5 seconds, less than or about 3 seconds, less than or about 1 second, or less, prior to beginning adjustment operations. Subsequent the first period of time, one or more conditions may be adjusted as will be discussed below. Although method 200 is described in a noted order of adjustments in FIG. 2, it is to be understood that any of the optional adjustments may be performed in any order as well as simultaneously in encompassed embodiments. Hence, the order of operations may not be limited in embodiments of the present technology.

The carbon-containing precursor may include one or more carbon-containing precursors and may include any hydrocarbon or carbon-and-hydrogen-containing precursor, although additional carbon-containing precursors may be utilized, including carbon-and-nitrogen-containing precursors, carbon-and-halogen-containing precursors, or any other carbon-containing precursor. For example, the carbon-containing precursor may be or include any alkane, alkene, alkyne, or aromatic material, which as non-limiting examples may include ethane, ethene, propane, propene, acetylene, or any higher-order hydrocarbon, or the precursor may be a material including one or more of carbon, hydrogen, oxygen, or nitrogen. The inert precursor may be any additional precursor or carrier gases that may be included, which may include Ar, He, Xe, Kr, nitrogen, or other precursors. Additionally, in some embodiments diatomic hydrogen may be included to further tune a carbon-to-hydrogen ratio of the precursors, which may impact film properties. In some embodiments a carbon-to-hydrogen ratio may be maintained to be less than or about 4:1, less than or about 3:1, less than or about 2:1, less than or about 1:1, or less, which may further facilitate limiting hydrogen incorporation during film formation.

During formation of the initiation layer, the hydrogen may not be included, which may otherwise reduce formation of a carbide-like film. Additionally, a carbon-to-hydrogen ratio may be maintained greater than or about 1:1, which may also improve formation of carbon-carbon double bonds, as well as carbon-metal triple bonds at the interface, while limiting oxygen content in the layers formed, which can reduce adhesion during subsequent deposition. To further facilitate development of longer chain carbon layers with increased double and triple bonding between carbon and the metal of the faceplate, or the metal of the metal oxide on the faceplate, processing characteristics may be maintained under a first set of conditions during the first period of time before adjustments are made to transition to a more thorough film deposition on the substrate.

For example, in some embodiments a flow rate of the carbon-containing precursor and a flow rate of the inert precursor may be maintained at first flow rates during formation of the initiation layer. The flow rates may be reduced relative to deposition flow rates, and a flow rate ratio between the precursors may be increased to further reduce hydrogen incorporation and increase longer-chain carbon incorporation, as well as development of a carbide-like film at the interface of the faceplate. For example, a flow rate of the carbon-containing precursor may be maintained at less than or about 300 sccm, and may be maintained at less that or about 250 sccm, less than or about 200 sccm, less than or about 150 sccm, less than or about 100 sccm, less than or about 50 sccm, or less.

Additionally, the inert precursor may be flowed at a flow rate of less than or about 1200 sccm, and may be flowed at a flow rate of less than or about 1100 sccm, less than or about 1000 sccm, less than or about 900 sccm, less than or about 800 sccm, less than or about 700 sccm, less than or about 600 sccm, less than or about 500 sccm, or less. However, a flow-rate ratio between the precursors may be maintained higher than subsequent the transition, and may be maintained during the initiation layer development at a flow-rate ratio of the inert precursor to the carbon-containing precursor of greater than or about 5:1, and may be maintained at a flow-rate ratio of greater than or about 6:1, greater than or about 7:1, greater than or about 8:1, greater than or about 9:1, greater than or about 10:1, greater than or about 12:1, greater than or about 14:1, greater than or about 16:1, greater than or about 18:1, greater than or about 20:1, or more.

Subsequent the first period of time, in some embodiments a flow rate of the carbon-containing precursor and a flow rate of the inert precursor may be increased at optional operation 210. The flow rates may be increased or ramped together, although in some embodiments the flow rate of the carbon-containing precursor may be increased less than the flow rate of the inert precursor. For example, in some embodiments the flow rate of the carbon containing precursor may be increased to greater than or about 200 sccm, and may be increased to greater than or about 250 sccm, greater than or about 300 sccm, greater than or about 350 sccm, greater than or about 400 sccm, greater than or about 450 sccm, greater than or about 500 sccm, or greater.

Additionally, the inert precursor may be increased to a flow rate of greater than or about 1500 sccm, and may be increased to a flow rate of greater than or about 1600 sccm, greater than or about 1700 sccm, greater than or about 1800 sccm, greater than or about 1900 sccm, greater than or about 2000 sccm, greater than or about 2100 sccm, greater than or about 2200 sccm, or more. In order to increase a deposition rate on the substrate subsequent the transition, a flowrate ratio of the inert precursor to the carbon-containing precursor may be reduced to less than or about 10:1, and may be reduced to less than or about 9:1, less than or about 8:1, less than or about 7:1, less than or about 6:1, less than or about 5:1, less than or about 4:1, less than or about 3:1, or less. Additional precursors may also be flowed subsequent the first period of time including additional carbon-containing precursors, diatomic hydrogen, nitrogen, any dopant materials, or any other material that may facilitate material growth on the substrate of a desired carbon-containing film.

Method 200 may also include adjusting the plasma power between the interfacial formation and deposition. For example, by performing the initiation portion at a first plasma power lower than a second plasma power at which deposition is performed, dissociation of the carbon-containing precursor may be better controlled, which may allow better development of a carbide-like material, with increased carbon double bonds and triple bonds as noted above. Accordingly, during the first period of time, a plasma power may be maintained at less than or about 1000 W, and may be maintained at less than or about 950 W, less than or about 900 W, less than or about 850 W, less than or about 800 W, less than or about 750 W, less than or about 700 W, less than or about 650 W, less than or about 600 W, less than or about 550 W, less than or about 500 W, less than or about 450 W, less than or about 400 W, less than or about 350 W, less than or about 300 W, less than or about 250 W, or less.

Subsequent the first period of time the plasma power may be increased at optional operation 215. The plasma generation may be maintained between the initiation period and the deposition portion, while adjustment to the parameters or conditions are performed. For example, subsequent the first period of time, in order to increase a deposition rate and facilitate formation of the desired carbon-containing material on the substrate, the plasma power may be increased. In some embodiments, the plasma power may be increased to greater than or about 1000 W, and may be increased to greater than or about 1200 W, greater than or about 1400 W, greater than or about 1600 W, greater than or about 1800 W, greater than or about 2000 W, greater than or about 2200 W, greater than or about 2400 W, greater than or about 2600 W, greater than or about 2800 W, or more.

Additional conditions within the processing chamber may also be adjusted between the initiation period and the deposition period. For example, in some embodiments a pressure may be reduced after a first period of time. By increasing the pressure during the initiation period, carbon-containing plasma effluents may have increased residence time adjacent the faceplate, which may increase the ability to form longer carbon chains, and increase double and triple bond formation as noted above. Accordingly, in some embodiments, a pressure within the processing region may be maintained at greater than or about 3 Torr during the initiation period, and may be maintained at greater than or about 5 Torr, greater than or about 7 Torr, greater than or about 10 Torr, greater than or about 12 Torr, greater than or about 15 Torr, greater than or about 18 Torr, greater than or about 20 Torr, greater than or about 25 Torr, greater than or about 30 Torr, greater than or about 35 Torr, greater than or about 40 Torr, greater than or about 45 Torr, greater than or about 50 Torr, or higher. Subsequent the first period of time, the pressure may be reduced to a lower pressure at optional operation 220, which may facilitate deposition. Accordingly, subsequent the first period of time, the pressure may be reduced to less than or about 20 Torr, and may be reduced to less than or about 15 Torr, less than or about 12 Torr, less than or about 10 Torr, less than or about 8 Torr, less than or about 6 Torr, less than or about 5 Torr, less than or about 4 Torr, less than or about 3 Torr, or less.

The location of the substrate support, which may operate as a grounded electrode in some embodiments, may also impact development of the initiation layer by controlling plasma characteristics. Accordingly, in some embodiments the position of the substrate support may be adjusted depending on the process conditions, and potentially the impact on the substrate. For example, in some embodiments the substrate support may be maintained closer to the faceplate during the initiation operations, which may improve the interfacial layer formation. However, in some embodiments the substrate or process may not be conducive to maintaining the substrate at this location, and hence, in some embodiments the substrate support may be maintained further from the faceplate to limit an impact on the substrate. Subsequent the first period of time, the substrate support position may be adjusted at optional operation 225, when deposition may be performed, and which may include raising or lowering the pedestal from the initiation position to an operational position for deposition.

Subsequent one or more adjustments after the first period of time when the interfacial layer is produced, a deposition operation may be performed at operation 230. The deposition may be performed for any amount of time, and to develop any thickness of carbon-containing material. Once the deposition has been completed, in some embodiments a chamber clean may be performed at optional operation 235. The chamber clean may utilize an oxygen-containing precursor, which may be plasma enhanced within the processing region to facilitate removal of residual materials. The cleaning process may remove some or all aspects of the residual carbon deposited about the processing chamber from the deposition, and may also remove the interfacial carbide-like material produced.

A subsequent substrate may then be disposed within the processing chamber, and method 200 may be repeated, which may include initiation process operations, as well as any of the transitional operations performed prior to deposition. During subsequent operations, the same or different process parameters may be adjusted subsequent the first period of time. By utilizing an oxide-coated faceplate during processing, process drift due to development of non-uniform oxidation on the faceplate may be reduced or limited. Additionally, by performing initiation operations according to embodiments of the present technology, adhesion issues related to utilizing oxide-coated faceplates may be reduced or limited. Consequently, particle and defect formation may be reduced, which may increase process quality and device yield.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a plasma of a carbon-containing precursor and an inert precursor within a processing region of a semiconductor processing chamber;
subsequent a first period of time, increasing a flow rate of the carbon-containing precursor and a flow rate of the inert precursor;
increasing a plasma power at which the plasma is formed; and
performing a deposition process on a semiconductor substrate disposed within the processing region of the semiconductor processing chamber.

2. The semiconductor processing method of claim 1, wherein the deposition process comprises forming a carbon-containing hardmask film.

3. The semiconductor processing method of claim 1, wherein the carbon-containing precursor and the inert precursor are flowed through a faceplate into the processing region of the semiconductor processing chamber, and wherein the faceplate is coated with an oxide of aluminum, silicon, yttrium, hafnium, or zirconium.

4. The semiconductor processing method of claim 1, further comprising:
subsequent the first period of time, reducing a pressure within the semiconductor processing chamber.

5. The semiconductor processing method of claim 1, further comprising:
performing a chamber clean with an oxygen-containing precursor.

6. The semiconductor processing method of claim 1, wherein the plasma power is increased from a first plasma power of less than or about 1000 W to a second plasma power of greater than or about 2000 W.

7. The semiconductor processing method of claim 1, further comprising:
subsequent the first period of time, adjusting a spacing of a substrate support on which the semiconductor substrate is disposed.

8. The semiconductor processing method of claim 1, wherein the flow rate of the carbon-containing precursor is increased less than the flow rate of the inert precursor subsequent the first period of time.

9. The semiconductor processing method of claim 1, wherein the first period of time is less than or about 1 minute.

10. A semiconductor processing method comprising:
forming a plasma of a carbon-containing precursor and an inert precursor within a processing region of a semiconductor processing chamber;
subsequent a first period of time, lowering a pressure within the processing region while continuing to form the plasma of the carbon-containing precursor and an inert precursor within a processing region of a semiconductor processing chamber; and
performing a deposition process on a semiconductor substrate disposed within the processing region of the semiconductor processing chamber.

11. The semiconductor processing method of claim 10, further comprising:
subsequent the first period of time, increasing a plasma power from a first plasma power below or about 1000 W to a second plasma power greater than or about 2000 W.

12. The semiconductor processing method of claim 10, further comprising:
subsequent the first period of time, increasing a flow rate of the carbon-containing precursor and a flow rate of the inert precursor, wherein the flow rate of the carbon-containing precursor is increased less than the flow rate of the inert precursor subsequent the first period of time.

13. The semiconductor processing method of claim 10, wherein the carbon-containing precursor and the inert precursor are flowed through a faceplate into the processing region of the semiconductor processing chamber, and wherein the faceplate is coated with an oxide of aluminum, silicon, yttrium, hafnium, or zirconium.

14. The semiconductor processing method of claim 10, wherein the first period of time is less than or about 1 minute.

15. The semiconductor processing method of claim 10, further comprising:
subsequent the first period of time, adjusting a spacing of a substrate support on which the semiconductor substrate is disposed.

16. A semiconductor processing method comprising:
forming a plasma of a carbon-containing precursor and an inert precursor within a processing region of a semiconductor processing chamber;
subsequent a first period of time, increasing a flow rate of the carbon-containing precursor and a flow rate of the inert precursor, wherein the flow rate of the carbon-containing precursor is increased less than the flow rate of the inert precursor subsequent the first period of time; and
performing a deposition process on a semiconductor substrate disposed within the processing region of the semiconductor processing chamber.

17. The semiconductor processing method of claim 16, further comprising:
subsequent the first period of time, reducing a pressure within the semiconductor processing chamber.

18. The semiconductor processing method of claim 16, further comprising:
subsequent the first period of time, increasing a plasma power within the processing region, wherein the plasma power is increased from a first plasma power of less than or about 1000 W to a second plasma power of greater than or about 2000 W.

19. The semiconductor processing method of claim 16, wherein the carbon-containing precursor and the inert precursor are flowed through a faceplate into the processing region of the semiconductor processing chamber, and wherein the faceplate is coated with a metal oxide.

20. The semiconductor processing method of claim 16, further comprising:
subsequent the first period of time, adjusting a spacing of a substrate support on which the semiconductor substrate is disposed.
